(19) United States
(12) Patent Application Publication
(10) Pub. No.: US 2007/0040279 A1
(43) Pub. Date: Feb. 22, 2007

(54) Switching device for altering built-in function of IC chip

(75) Inventors: Chung Ju Wu, Kao Hsiung City (TW); Cheng Fang Chiu, Hsin Chu City (TW)

Correspondence Address: BIRCH STEWART KOLASCH & BIRCH, PO BOX 747, FALLS CHURCH, VA, 22040-0747, US

(73) Assignee: Silicon Integrated Systems Corp.

(21) Appl. No.: 11/265,298

(22) Filed: Nov. 3, 2005

(30) Foreign Application Priority Data
Aug. 19, 2005 (TW) 094128527

(51) Int. Cl. H01L 23/52

(52) U.S. Cl. 257/777

(57) ABSTRACT

A switching device provided on a package substrate for altering the built-in function of an IC chip includes a first contact, a second contact, and a conductive layer. The first contact is electrically connected to a signal-receiving end of the package substrate, and the second contact is electrically connected to a voltage source of the package substrate. The conductive layer is used for electrically connecting the first contact with the second contact.

### BACKGROUND OF THE INVENTION

(a) Field of the Invention

The invention relates to a switching device, particular relates to a switching device capable of altering built-in function of an integrated circuit (IC) chip.

(b) Description of the Related Art

Typically, it can be found that sold IC chips having distinct built-in functions and models are originated from the same batch of wafers. The IC chips originated from the same batch of wafers should, theoretically, have the same circuits thereon and thus the same built-in functions; however, they may perform respective functions during operation simply by additionally adding a specific treatment in their packaging processes.

FIG. 1 shows a schematic diagram illustrating a typical IC chip. The IC chip 10 consists of a zero-ohm resistor Z, a package substrate 11, a die 12, and a plurality of solder balls 13. A typical way to alter the built-in function of an IC chip is to connect the zero-ohm resistor Z with two bonding pads (not shown) in the surface mounting of passive components, so that a voltage level variation caused by the connection of the two bonding pads allows to alter the built-in function of the IC chip 10. Thereby, different chips originated from the same batch of wafers may have their respective functions according to clients' requirements to result in a reduced stock and wider application of the IC chips.

However, though the built-in function modification for an IC chip may be achieved by means of a zero-ohm resistor due to its capability of transforming electric properties, the size and weight of the zero-ohm resistor will increase those of the IC chip incorporating that resistor. Further, manufacturing cost for the mass production of IC chips is considerable increased because of the added cost of the zero-ohm resistor. For instance, the mass production of five million IC chips per month requires additional five million zero-ohm resistors. Besides, another disadvantage lies in that the zero-ohm resistor is liable to be reworked due to its massive appearance.

### BRIEF SUMMARY OF THE INVENTION

In view of the above-mentioned problems, an object of the invention is to provide a switching device having a reduced size and weight.

Another object of the invention is to provide a switching device that allows for decreasing the manufacturing cost and the possibility of being reworked by others.

To achieve the above-mentioned object, a switching device provided on a package substrate for altering the built-in function of an IC chip includes a first contact, a second contact, and a conductive layer. The first contact is electrically connected to a signal-receiving end of the package substrate, and the second contact is electrically connected to a voltage source of the package substrate. The conductive layer is used for electrically connecting the first contact with the second contact. When the first and the second contacts are connected with each other, the voltage level of the signal-receiving end is switched from a preset voltage level of the IC chip to a voltage level from the voltage source.

Further, the invention provides a method for altering the built-in function of an IC chip. The method includes the following steps:

Providing two contacts on a package substrate, wherein one contact is connected to a signal-receiving end of the package substrate, and the other contact is connected to a voltage source of the package substrate; placing a stencil plate on the package substrate, the stencil plate being provided with an opening whose location corresponds the two contacts on the package substrate; performing solder-paste printing on the stencil plate to allow the two contacts to be electrically connected with each other; and connecting the two contacts firmly following by surface mount reflow procedure or curing with high temperature oven solidifying the solder-paste.

Through the design of the invention, the inventive switching device can considerably reduce the manufacture cost of an IC chip, because the switching device is formed by the originally passive components adding on package substrate procedures with solder-paste printing process, without additional process solely prepared for producing it. Specifically, simply by providing an opening on the stencil sheet at one location corresponding to that of the switching device, the conductive layer is easily formed by solder-paste printing with the two contacts enclosed with the solder paste. Also, the inventive switching device, similar to a tack on the package substrate, is so small as not to be easily recognized, thus preventing itself from being reworked by others. The small geometry size of the inventive switching device can also increase the package substrate routing flexibility than the traditional zero-ohm resistor pads design. Accordingly, the inventive switching device may reduce the manufacture cost, the overall size and weight of an IC chip, and may prevent possibility of being reworked by others.

### BRIEF DESCRIPTION OF THE DRAWINGS

FIG. 1 shows a schematic diagram illustrating a typical IC chip.

FIG. 2A shows a schematic diagram illustrating an IC chip of the invention, and FIG. 2B shows a side view of the IC chip.

FIG. 3A shows a schematic diagram illustrating a configuration of a switching device according to the invention. FIG. 3B shows a schematic diagram illustrating the switching device covered with a conductive layer.

FIGS. 4A and 4B illustrating another embodiment of the switching device according to the invention.

FIGS. 5A and 5B illustrating another embodiment of the switching device according to the invention.

FIGS. 6A and 6B illustrating another embodiment of the switching device according to the invention.

FIG. 7 shows a flow diagram illustrating the steps of a method for altering the built-in function of an IC chip.

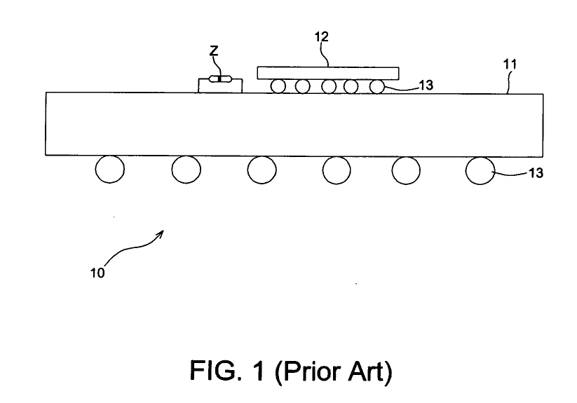

### DETAILED DESCRIPTION OF THE INVENTION

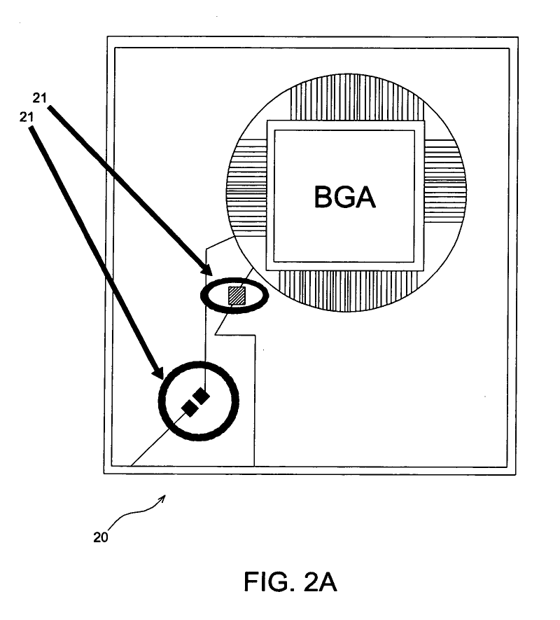

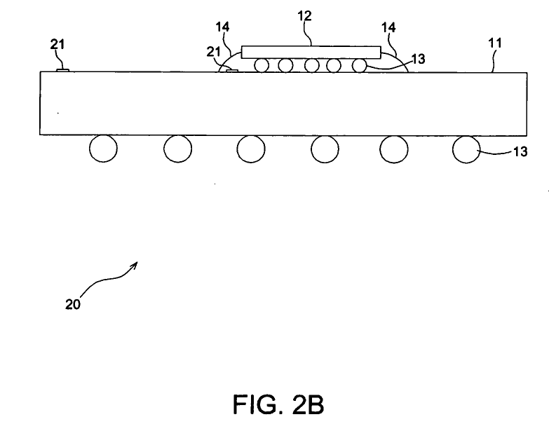

FIG. 2A shows a schematic diagram illustrating an IC chip 20 of the invention, where a switching device 21 used for altering the built-in function of the IC chip 20 is indicated by a circle notation. FIG. 2B shows a side view of the IC chip 20. The IC chip 20 includes two switching devices 21, a package substrate 11, a die 12, a plurality of solder balls 13, and flip chip (FC) underfill 14. The location of the switching device 21 on the package substrate 11 is not limited. For instance, one of the two switching devices 21 is placed neighboring one side of the die 12 and covered with FC underfill 14, so that it may not be recognized to prevent itself from being reworked by others. In comparison, the other switching device 21 is placed neighboring the edge of the package substrate 11 (far from the die 12), so that the formation of a conductive layer of the switching device 21 is easily achieved without disturbing other arrangements of conducting trace routing on package substrate. Even the switching device 21 is placed far from the die 12 and not covered with FC underfill 14, it may not be recognized since its appearance is similar to that of a tack on the package substrate 11.

Note that the number of switching devices provided on a single package substrate is not limited. Though one switching device is enough to alter the built-in function of the IC chip, providing two or more switching devices may increase the number of possible function-switchings.

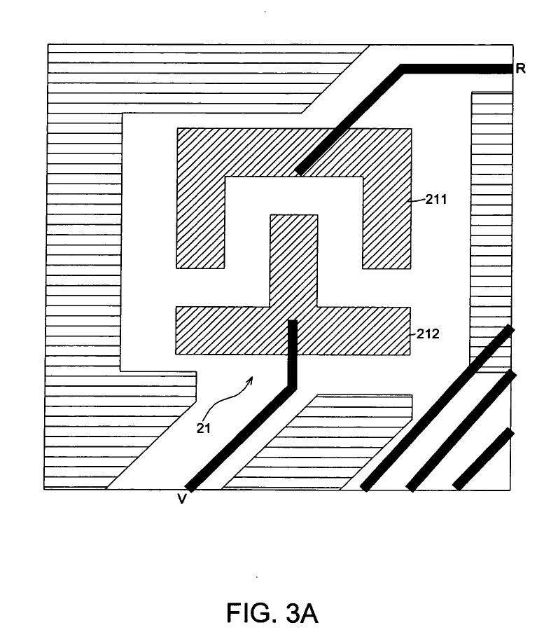

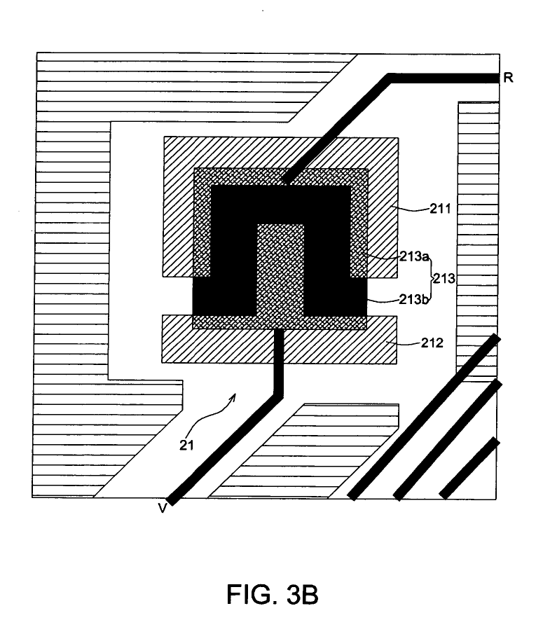

FIG. 3A shows a schematic diagram illustrating a configuration of the switching device 21. FIG. 3B shows a schematic diagram illustrating the switching device 21 covered with a conductive layer. The switching device 21 includes a first contact 211, a second contact 212, and a conductive layer 213. As shown in FIG. 3B, the occupied area of the conductive layer 213 is a square including the area indicated by a mesh pattern 213a and a deep black color 213b. On the package substrate 11, a signal-receiving end R and a voltage source V are provided in advance. When the signal-receiving end R receives a voltage value that is equal to a preset voltage of the IC chip 20, the IC chip 20 will perform its original preset function. On the contrary, when the signal-receiving end R receives a voltage value from the voltage source V other than the preset voltage, the IC chip 20 will perform another preset function.

As shown in FIG. 3A and FIG. 3B, the first contact 211 is connected to the signal-receiving end R, and the second contact 212 is connected to the voltage source V. The first and second contacts may be metallic bonding pads, via holes, or any electrical connection point made of a material with high electrical conductivity such as tin, lead, copper, gold and silver.

The conductive layer 213 is used to alter the built-in function of the IC chip 20 as it is connected with both the first contact 211 and the second contact 212. The conductive layer 213 is formed by the process of solder-paste printing, and its formation depends on whether a stencil plate used in substrate solder-paste printing has an opening. Specifically, once no opening is formed above the first contact 211 and the second contact 212 on the stencil plate, the conductive layer 213 will not be formed between them after solder-paste printing and will result in an “off” state. In that case, the signal-receiving end R receives a voltage value equal to a preset voltage, and the IC chip 20 remains to perform its original preset function. On the contrary, if the stencil plate is provided with an opening located upon the first contact and second contacts, the conductive layer 213 will be formed between the first and second contacts after solder-paste printing to result in an “on” state. In that case, the signal-receiving end R receives a voltage value other than the preset voltage, and the IC chip 20 will perform another preset function.

Note that the occupied areas and shapes of the first and the second contacts are not limited. For example, referring to FIG. 3, the first and the second contacts 211 and 212 with no symmetry are different in both occupied area and shape, so that the cohesion of solder paste is eliminated in a flip chip reflow process. Under the circumstance, the conductive layer 213 can be connected with the first and the second contacts more precisely. Further, in this embodiment, the conductive layer 213 is formed by the process of solder-paste printing. However, the conductive layer 213 may be formed by other semiconductor fabrication process, such as the process of silver-epoxy dispensing. The conductive layer 213 may be made of a material with high electrical conductivity such as tin, lead, copper, gold and silver. Besides, in this embodiment, the first contact 211 is connected to the signal-receiving end R, and the second contact 212 is connected to the voltage source V. However, the first contact 211 may be connected to the voltage source V, and the second contact 212 may be connected to the signal-receiving end R.

Compared with the conventional zero-ohm resistor used for altering the built-in IC chip function, the inventive switching device 21 considerably reduces the manufacture cost of an IC chip, because the switching device 21 is formed by the originally required solder-paste printing process, such as the passive components adding processes popular used in current work, without adding additional process solely for producing it. Specifically, simply by providing an opening on the stencil plate at one location corresponding to that of the switching device, the conductive layer 213 is easily formed by solder-paste printing with the two contacts 211 and 212 enclosed with the solder paste. Further, in case more than two switching devices are needed to increase the number of possible function-switchings of the IC chips 20, it can be done simply by providing another stencil plate having opening corresponding to another switching device or having plural openings on one stencil plate at related locations above the switching devices. Hence, for altering the built-in functions of five million IC chips, only pieces of stencil plates are enough to achieve the function switch operating according to the invention, while five million of zero-ohm resistors are required according to the conventional design. Also, the switching device 21, similar to a tack on the package substrate 11, is so small as not to be easily recognized, thus preventing itself from being reworked by others. Accordingly, the inventive switching device may reduce the manufacture cost, the overall size and weight of an IC chip, and possibility of being reworked by others.

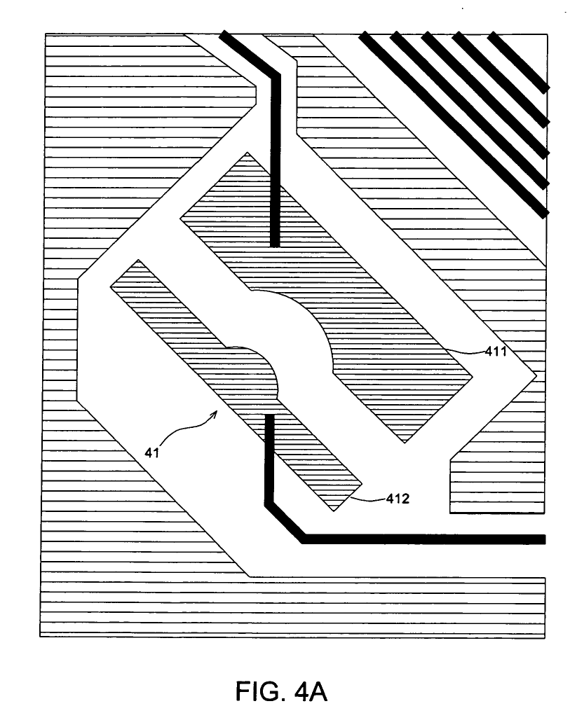

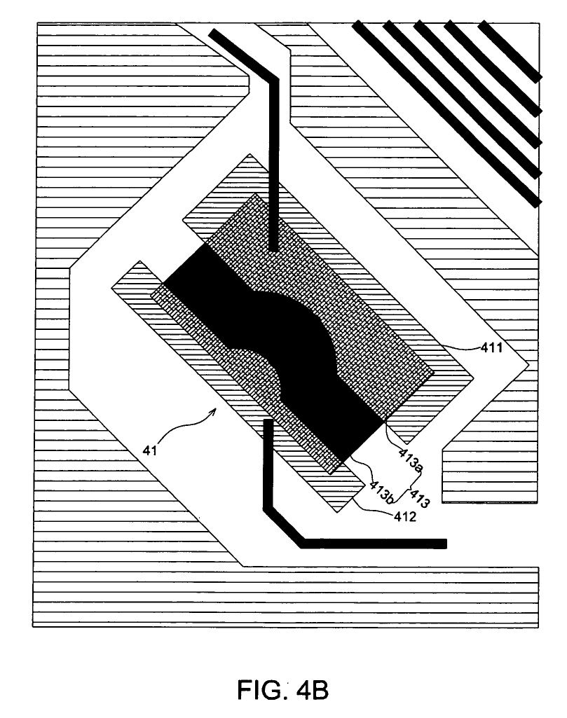

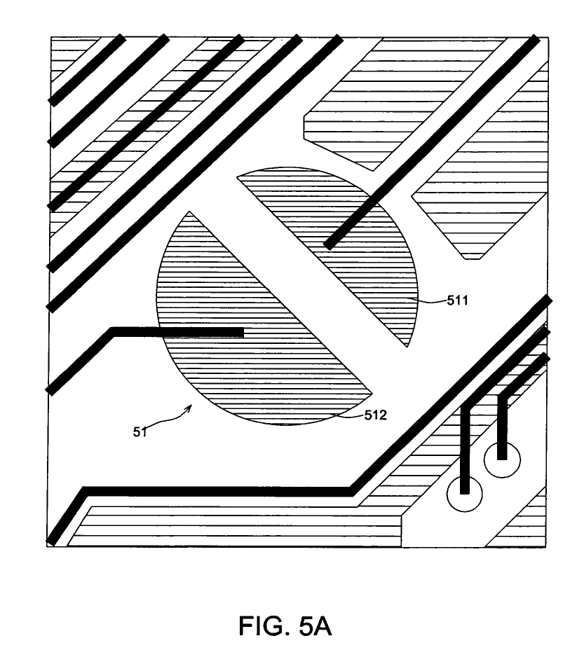

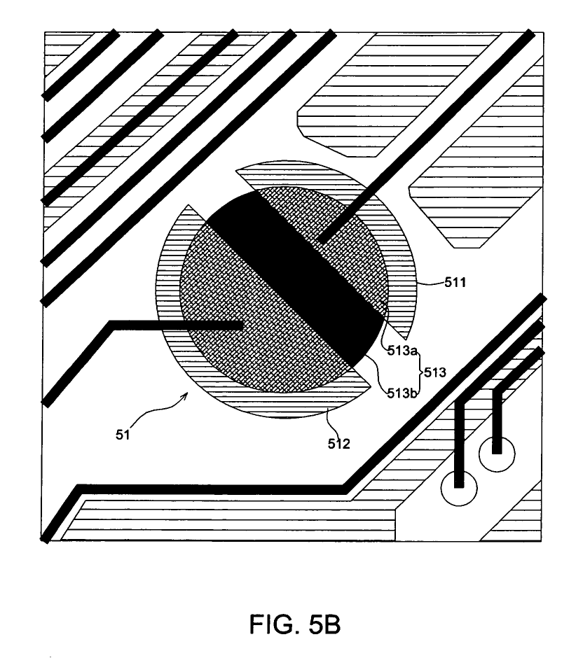

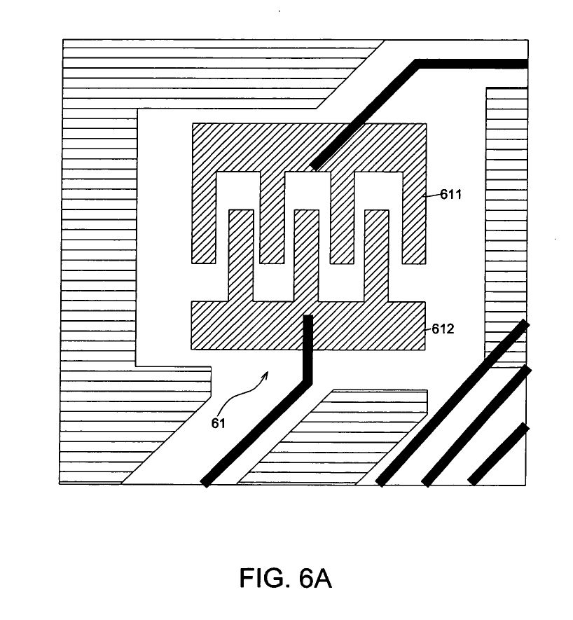

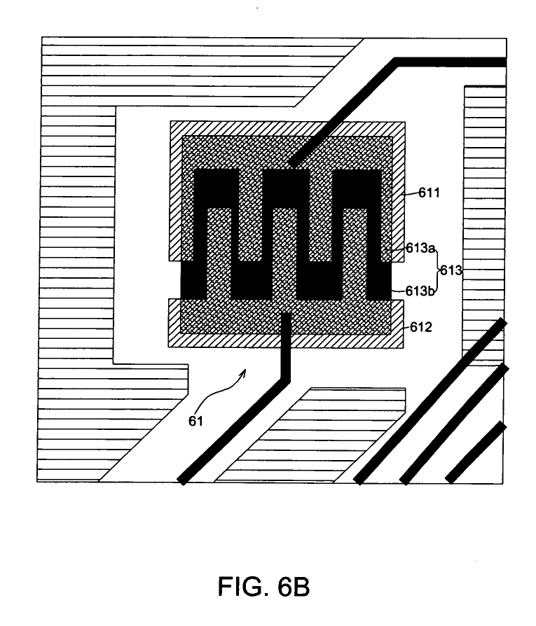

FIGS. 4A and 4B illustrating another embodiment of the switching device according to the invention. The switching device 41 includes a first contact 411, a second contact 412, and a conductive layer 413, and the occupied area of the conductive layer 413 is a square including the area indicated by a mesh pattern 413a and a deep black color 413b, as shown in FIG. 4B. FIGS. 5A and 5B illustrating another embodiment of the switching device according to the invention. The switching device 51 includes a first contact 511, a second contact 512, and a conductive layer 513, and the occupied area of the conductive layer 513 is circular including the area indicated by a mesh pattern 513a and a deep black color 513b, as shown in FIG. 5B. Further, as shown in FIGS. 6A and 6B, the contacts 611 and 612 may be designed as comb structures to aid the connection between the conductive layer 613 and the contacts 611 and 612. Note that the occupied area of the conductive layer 613 is a square shown in FIG. 6B including the area indicated by a mesh pattern 613a and a deep black color 613b. The characteristics, configurations, and operations of the switching devices 41, 51 and 61 are all identical to the switching device 21, thus not explaining in detail.

Besides, the plate used in the process of solder-paste printing includes, but is not limited to, the stencil plate and steel sheets. Other material such as copper, iron and plastic may also be used.

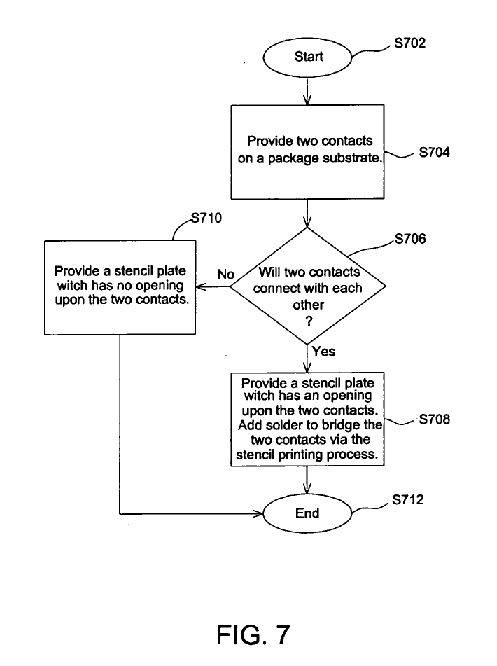

FIG. 7 shows a flow diagram illustrating the steps of a method for altering the built-in function of an IC chip.

Step S702: Start.

Step S704: Provide two contacts on a package substrate, where one contact is connected to a signal-receiving end of the package substrate, and the other contact is connected to a voltage source of the package substrate.

Step S706: Determine whether to electrically connect the two contacts with each other. If yes, go to step S708; if no, go to step S710.

Step S708: Provide a stencil plate on the package substrate, where the stencil plate has an opening whose location corresponding to that of the two contacts. Add solder via the opening to allow the two contacts to be electrically connected with each other for achieving the function altering by the following solder paste printing and surface mount reflow process. Where the solder paste printing and surface mount reflow process can melt the solder and connect the two contacts together. Then, go to step S712.

Step S710: Provide a stencil plate on the package substrate, where the stencil plate has no opening corresponding to the two contacts, and add solder on the stencil plate. Since no opening is provided, the two contacts fail to be electrically connected with each other, and the function of the IC chip remains the same as a result. Then, go to step S712.

Step S712: End.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A switching device provided on a package substrate for altering the built-in function of an IC chip, comprising:
a first contact electrically connected to a signal-receiving end of the package substrate;
a second contact electrically connected to a voltage source of the package substrate; and
a conductive layer for electrically connecting the first contact with the second contact.

2. The switching device as claimed in claim 1, wherein the voltage level of the signal-receiving end is switched from a preset voltage level of the IC chip to a voltage level from the voltage source when the first and the second contacts are connected with each other.

3. The switching device as claimed in claim 1, wherein the contact is a bonding pad.

4. The switching device as claimed in claim 1, wherein the contact is a via hole.

5. The switching device as claimed in claim 1, wherein the material of the conductive layer is selected from the group consisting of tin, lead, copper, gold, silver, and a combination of at least two of them.

6. The switching device as claimed in claim 1, wherein the material of the contact is selected from the group consisting of tin, lead, copper, gold, silver, and a combination of at least two of them.

7. The switching device as claimed in claim 1, wherein the conductive layer is formed by the process of solder-paste printing.

8. The switching device as claimed in claim 1, wherein the conductive layer is formed by the process of silver-epoxy dispensing.

9. The switching device as claimed in claim 1, wherein the switching device is placed neighboring one side of a die on the package substrate.

10. The switching device as claimed in claim 9, wherein the switching device is cover with flip chip underfill.

11. The switching device as claimed in claim 1, wherein the switching device is placed neighboring one side of the package substrate.

12. The switching device as claimed in claim 1, where the occupied area of the first contact is different to that of the second contact.

13. The switching device as claimed in claim 1, where the occupied area of the first contact is the same as that of the second contact.

14. The switching device as claimed in claim 1, where the shape of the first contact is different to that of the second contact.

15. The switching device as claimed in claim 1, where the shape of the first contact is the same as that of the second contact.

16. A method for altering the built-in function of an IC chip, comprising the steps of:
providing two contacts on a package substrate, wherein one contact is connected to a signal-receiving end of the package substrate, and the other contact is connected to a voltage source of the package substrate;
placing a plate on the package substrate, the plate being provided with an opening whose location corresponds the two contacts on the package substrate; and
performing solder-paste printing on the plate to allow the two contacts to be electrically connected with each other.

17. The method as claimed in claim 16, wherein a conductive layer is formed on the package substrate by the solder-paste printing, and the conductive layer is electrically connected with both the two contacts.

18. The method as claimed in claim 16, wherein a conductive layer is formed on the package substrate by the silver-epoxy dispensing process, and the conductive layer is electrically connected with both the two contacts.

19. The method as claimed in claim 16, wherein, in the step of solder-paste printing, the solder-paste is solidified by surface mounting reflow procedure or cured by oven to firmly connect the two contacts.
